(19) United States
(12) Patent Application Publication
(10) Pub. No.: US 2016/0079904 A1
(43) Pub. Date: Mar. 17, 2016

(54) DRIVE UNIT EMPLOYING GALLIUM NITRIDE SWITCHES

(71) Applicant: OTIS ELEVATOR COMPANY, Farmington, CT (US)

(72) Inventors: Shashank Krishnamurthy, Rocky Hill, CT (US); Xin Wu, Glastonbury, CT (US); William A. Veronesi, Hartford, CT (US); Kyle W. Rogers, Stamford, CT (US); Daryl J. Marvin, Farmington, CT (US)

(21) Appl. No.: 14/785,023

(22) PCT Filed: Apr. 17, 2013
(86) PCT No.: PCT/US2013/036899

§ 371 Date: Oct. 16, 2015

(51) Int. Cl. H02P 27/06; B66B 1/46; B66B 11/04; H03K 17/081; H03K 17/16

(52) U.S. Cl. CPC H02P 27/06; H03K 17/08104; H03K 17/162; H03K 17/08116; H03K 17/168; B66B 11/04; B66B 1/46

(57) ABSTRACT

A switching assembly for use in a drive unit for driving a motor. The switching assembly includes a gallium nitride switch having a gate terminal, drain terminal and source terminal; a gate driver generating a drive signal; a gate drive circuit including a turn on resistor in series with the gate driver and the gate terminal and a clamping circuit connected across the gate terminal and the source terminal, a turn on drive signal from the gate driver being applied to the gate terminal through the turn on resistor; and a snubber circuit connected across the drain terminal and source terminal.

### FIELD OF INVENTION

The subject matter disclosed herein relates generally to the field of drive units, and more particularly, to a drive unit using gallium nitride switches.

### DESCRIPTION OF RELATED ART

Existing elevator drive units are based on silicon insulated-gate bipolar transistors (IGBTs) and metal-oxide-semiconductor field-effect transistors (MOSFETs). The inherent switching characteristics of silicon based devices limit the practical maximum pulse width modulation (PWM) switching frequency, minimum loss, and minimum size of elevator drive units. Practical switching frequencies of silicon based devices are typically in the audible range and can lead to acoustic noise problems from the drive units and attached motors.

It is desirable to reduce the size of the elevator drive unit. Losses in existing, well designed drive units are on the order of 3-5%. These losses determine the size of heat sinks, and heat sink size is a major contributor to overall elevator drive unit size. Elevator drive unit size is also limited by inherent voltage blocking capability. Switching device size is another factor in overall drive unit size.

### BRIEF SUMMARY

An exemplary embodiment includes a switching assembly for use in a drive unit for driving a motor. The switching assembly includes a gallium nitride switch having a gate terminal, drain terminal and source terminal; a gate driver generating a drive signal; a gate drive circuit including a turn on resistor in series with the gate driver and the gate terminal and a clamping circuit connected across the gate terminal and the source terminal, a turn on drive signal from the gate driver being applied to the gate terminal through the turn on resistor; and a snubber circuit connected across the drain terminal and source terminal.

Another exemplary embodiment includes a drive unit for driving a motor. The drive unit includes a controller generating a control signal; a first voltage bus and a second voltage bus; a switching assembly connected between one of the first voltage bus and the second voltage bus and an output, the switching assembly including: a gallium nitride switch having a gate terminal, drain terminal and source terminal; a gate driver generating a drive signal in response to the control signal; a gate drive circuit including a turn on resistor in series with the gate driver and the gate terminal and a clamping circuit connected across the gate terminal and the source terminal, a turn on drive signal from the gate driver being applied to the gate terminal through the turn on resistor; and a snubber circuit connected across the drain terminal and source terminal.

Another exemplary embodiment includes an elevator drive unit for driving a motor to impart motion to an elevator car. The drive unit includes a controller generating a control signal; a first voltage bus and a second voltage bus; a switching assembly connected between one of the first voltage bus and the second voltage bus and an output, the switching assembly including: a gallium nitride switch having a gate terminal, drain terminal and source terminal; a gate driver generating a drive signal in response to the control signal; a gate drive circuit including a turn on resistor in series with the gate driver and the gate terminal and a clamping circuit connected across the gate terminal and the source terminal, a turn on drive signal from the gate driver being applied to the gate terminal through the turn on resistor; and a snubber circuit connected across the drain terminal and source terminal.

Other aspects, features, and techniques of embodiments of the invention will become more apparent from the following description taken in conjunction with the drawings.

### BRIEF DESCRIPTION OF THE DRAWINGS

Referring now to the drawings wherein like elements are numbered alike in the FIGURES:

FIG. 1 is a schematic diagram of an elevator drive unit in an exemplary embodiment;

FIG. 2 depicts a switching assembly in an exemplary embodiment; and

FIG. 3 depicts a switching assembly in another exemplary embodiment.

### DETAILED DESCRIPTION

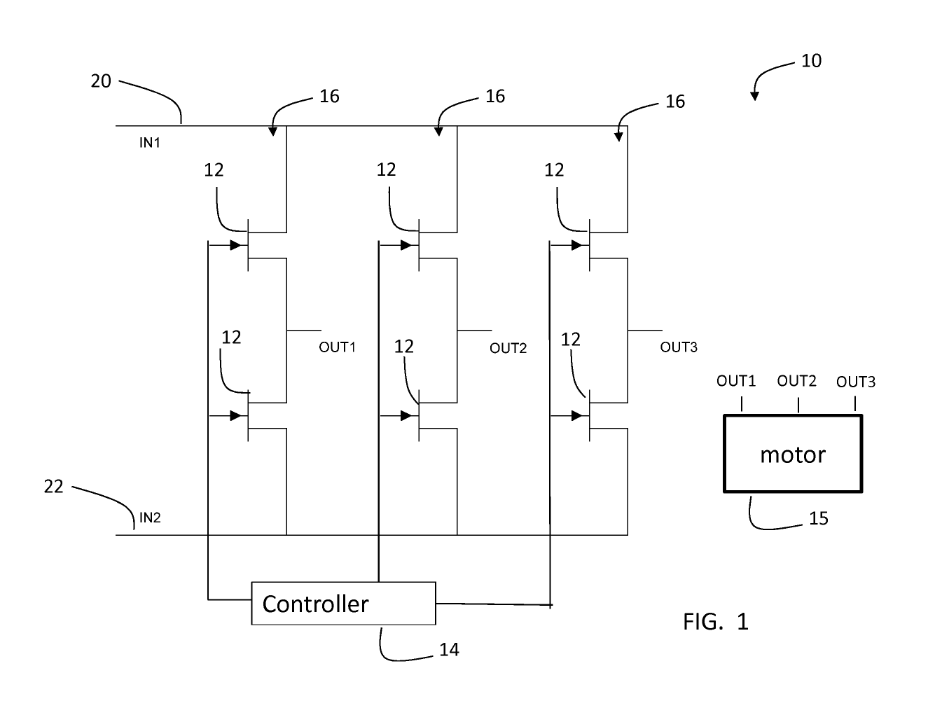

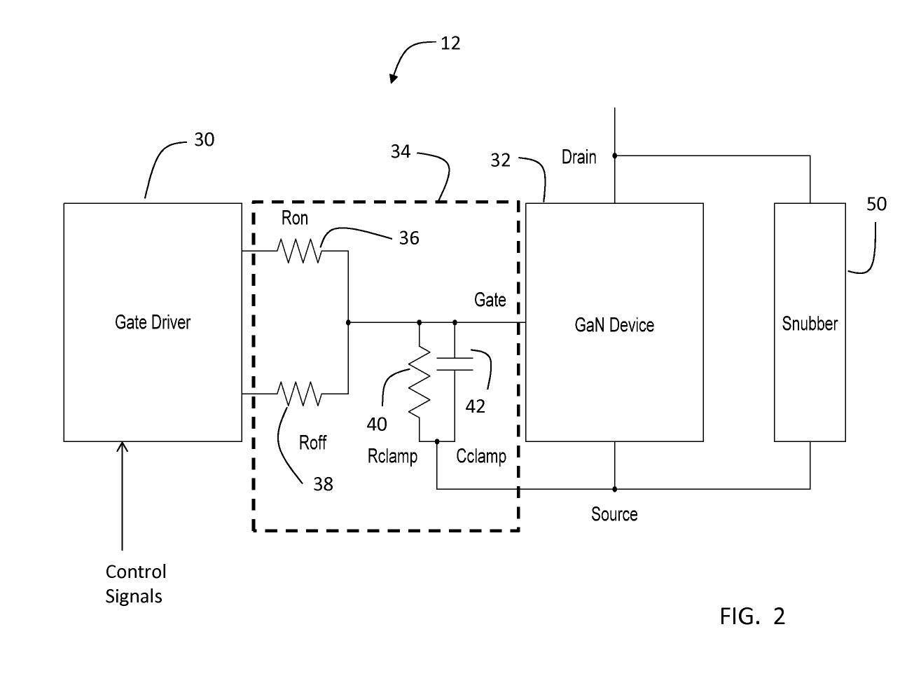

FIG. 1 is a schematic diagram of a drive unit 10 in an exemplary embodiment. Drive unit 10 may be employed as part of an elevator or escalator, in exemplary embodiments. Drive unit 10 includes a number of switching assemblies 12 driven by a controller 14. Controller 14 provides control signals to a gate driver 30 (FIG. 2) to control switches in the switching assemblies 12 as described herein. Control signals from controller 14 may be pulse width modulation (PWM) control signals in exemplary embodiments. Controller 14 may be implemented using a general-purpose microprocessor executing a computer program stored on a storage medium to perform the operations described herein. Alternatively, controller 14 may be implemented in hardware (e.g., ASIC, FPGA) or in a combination of hardware/software. Switching assemblies 12 may contain a plurality of switches, a gate driver and other components as described in further detail herein with reference to FIG. 2.

Drive unit 10 includes three phase legs 16, each phase leg 16 including two switching assemblies 12. Each phase leg 16 is connected to a first DC voltage bus 20 and a second DC voltage bus 22. In operation, controller 14 turns switching assemblies 12 on and off to apply either the first voltage from first DC voltage bus 20 or a second voltage from second DC voltage bus 22 to generate an AC signal at terminals OUT1, OUT2 and OUT3. In exemplary embodiments, terminals OUT 1, OUT 2 and OUT 3 are coupled to a motor 15, for example, a three phase elevator motor or escalator motor. Although three phase legs 16 are shown in FIG. 1, embodiments described herein may be used with any number of phases, including single phase drive units. FIG. 1 depicts a two level drive unit, but embodiments described herein may be used with any multilevel drive unit (e.g., three level neutral point clamped drive units). Drive unit 10 may operate as an inverter (DC to AC) in a drive mode or as a rectifier (AC to DC) in a regenerative mode.

FIG. 2 depicts a switching assembly 12 in an exemplary embodiment. Switching assembly 12 includes a gate driver 30 that provides drive signals to a gate terminal of switch 32. Switch 32 is a gallium nitride transistor in an exemplary embodiment. Gate driver 30 receives control signals from controller 14 to generate drive signals for switch 32. Control signals from controller 14 may be pulse width modulation signals. A single switch 32 is shown in FIG. 2, but it is understood that switching assembly 12 may include a plurality of switches 32 driven by gate driver 30. Switches 32 in switching assembly 12 may be placed in parallel to increase current capacity.

Gallium nitride switches 32 are high speed switching devices and can be turned on and off in nanoseconds. Due to the fast switching, switches 32 can produce very high dv/dt which can significantly increase electromagnetic interference (EMI) and damage both the drive unit 10 and the driven component (e.g., motor 15). To manage the switching speed of switches 32, a gate drive circuit 34 is positioned between gate driver 30 and switch 32. The gate drive circuit 34 includes elements to control the switching speed of switch 32.

Gate drive circuit 34 includes a turn on resistor 36 and a turn off resistor 38, in series with the gate terminal of switch 32. When switch 32 is turned on, a turn on drive signal is applied through turn on resistor 36. When switch 32 is turned off, a turn off drive signal is applied through turn off resistor 38. In general, the turn on resistor 36 may have a larger magnitude than turn off resistor 38. Increasing the turn on resistor 36 reduces overshoot of the gate terminal voltage.

Gate drive circuit 34 includes a gate clamping circuit including clamping resistor 40 and clamping capacitor 42. Clamping resistor 40 and clamping capacitor 42 are in parallel with each other, and connected across the gate terminal and source terminal of switch 32. By selecting the values of clamping resistor 40 and clamping capacitor 42, the switching speed of switch 32 can be controlled. This helps reduce dv/dt of switch 32.

Switching assembly 12 also includes a snubber circuit 50 coupled across the drain terminal and source terminal of switch 32. Snubber circuit 50 may be implemented using a resistor-capacitor circuit, a resistor-capacitor-diode circuit, or other known snubber circuit configurations. Snubber circuit 50 prevents voltage overshoot at the output of switch 32. By controlling the values of the turn on resistor 36 and turn off resistor 38, as well as the snubber circuit value, the turn on time and turn off time of switch 32 can be increased to reduce the voltage rise, and hence dv/dt, of switch 32. This enables a significant increase in life and reliability of drive units using gallium nitride devices.

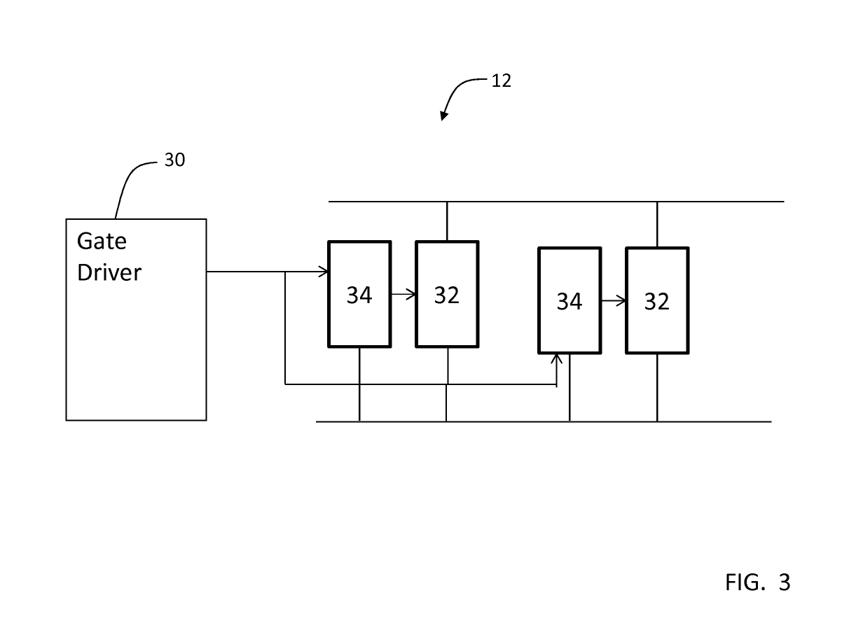

FIG. 3 depicts a switching assembly 12 having multiple switches 32. As shown, two switches 32 are in parallel, driven by a common gate driver 30. Snubber circuits 50 are not shown for ease of illustration. It is understood that more than two switches 32 may be placed in parallel and embodiments are not limited to two switches 32. Embodiments may include 8, 12, 16 or more switches in parallel. Each switch 32 includes a gate drive circuit 34 as discussed above. Arranging switches 32 in parallel increases current capability of the switching assembly 12. As noted above, switches 32 may also be arranged in series in alternate embodiments.

A drive unit using gallium nitride switches has many advantages over those based on silicon devices. The inherent switching characteristics of gallium nitride devices versus silicon devices raises the practical maximum PWM switching frequency, reduces minimum loss, and reduces minimum size of drive units, such as elevator drive units. Practical switching frequencies well above the audible range are possible using gallium nitride devices, which eliminates acoustic noise problems from the drive units and attached motors. Losses in a gallium nitride drive unit can be on the order of 1-2%. These reduced losses reduce the required size and/or number of heat sinks, or eliminates the need for heat sinks altogether. Heat sink size is an important contributor to overall elevator drive unit size. Elevator drive design depends on voltage rating of available device and device arrangements needs to be used to realize appropriate drive voltage. Small, efficient drive units provide increased flexibility in drive unit location, simplifying installation and servicing.

The terminology used herein is for the purpose of describing particular embodiments only and is not intended to be limiting of the invention. While the description of the present invention has been presented for purposes of illustration and description, it is not intended to be exhaustive or limited to the invention in the form disclosed. Many modifications, variations, alterations, substitutions, or equivalent arrangement not hereto described will be apparent to those of ordinary skill in the art without departing from the scope and spirit of the invention. Additionally, while the various embodiments of the invention have been described, it is to be understood that aspects of the invention may include only some of the described embodiments. Accordingly, the invention is not to be seen as being limited by the foregoing description, but is only limited by the scope of the appended claims.

1. A switching assembly for use in a drive unit for driving a motor, the switching assembly comprising:
a gallium nitride switch having a gate terminal, drain terminal and source terminal;
a gate driver generating a drive signal;
a gate drive circuit including a turn on resistor in series with the gate driver and the gate terminal and a clamping circuit connected across the gate terminal and the source terminal, a turn on drive signal from the gate driver being applied to the gate terminal through the turn on resistor; and
a snubber circuit connected across the drain terminal and source terminal.

2. The switching assembly of claim 1 further comprising:
a turn off resistor in series with the gate driver and the gate terminal, a turn off drive signal from the gate driver being applied to the gate terminal through the turn off resistor.

3. The switching assembly of claim 1 wherein:
the clamping circuit includes a capacitor connected across the gate terminal and the source terminal.

4. The switching assembly of claim 1 wherein:
the clamping circuit includes a resistor and capacitor in parallel, the resistor and capacitor connected across the gate terminal and the source terminal.

5. The switching assembly of claim 1 further comprising:
a second gallium nitride switch having a gate terminal, drain terminal and source terminal, the second gallium nitride switch in parallel with the gallium nitride switch;
a second gate drive circuit including a second turn on resistor in series with the gate driver and the gate terminal of the second gallium nitride switch and a second clamping circuit connected across the gate terminal and the source terminal of the second gallium nitride switch, the turn on drive signal from the gate driver being applied to the gate terminal of the second gallium nitride switch through the second turn on resistor.

6. The switching assembly of claim 1 wherein:
wherein the drive unit is configured to operate without a dedicated heat sink.

7. A drive unit for driving a motor, the drive unit comprising:
a controller generating a control signal;
a first voltage bus and a second voltage bus;
a switching assembly connected between one of the first voltage bus and the second voltage bus and an output, the switching assembly including:
a gallium nitride switch having a gate terminal, drain terminal and source terminal;
a gate driver generating a drive signal in response to the control signal;
a gate drive circuit including a turn on resistor in series with the gate driver and the gate terminal and a clamping circuit connected across the gate terminal and the source terminal, a turn on drive signal from the gate driver being applied to the gate terminal through the turn on resistor; and
a snubber circuit connected across the drain terminal and source terminal.

8. The drive unit of claim 7, the switching assembly further comprising:
a turn off resistor in series with the gate driver and the gate terminal, a turn off drive signal from the gate driver being applied to the gate terminal through the turn off resistor.

9. The drive unit of claim 7 wherein:
the clamping circuit includes a capacitor connected across the gate terminal and the source terminal.

10. The drive unit of claim 7 wherein:
the clamping circuit includes a resistor and capacitor in parallel, the resistor and capacitor connected across the gate terminal and the source terminal.

11. The drive unit of claim 7, the switching assembly further comprising:
a second gallium nitride switch having a gate terminal, drain terminal and source terminal, the second gallium nitride switch in parallel with the gallium nitride switch;
a second gate drive circuit including a second turn on resistor in series with the gate driver and the gate terminal of the second gallium nitride switch and a second clamping circuit connected across the gate terminal and the source terminal of the second gallium nitride switch, the turn on drive signal from the gate driver being applied to the gate terminal of the second gallium nitride switch through the second turn on resistor.

12. The drive unit of claim 7 wherein:
wherein the drive unit is configured to operate without a dedicated heat sink.

13. An elevator drive unit for driving a motor to impart motion to an elevator car, the drive unit comprising:
a controller generating a control signal;
a first voltage bus and a second voltage bus;
a switching assembly connected between one of the first voltage bus and the second voltage bus and an output, the switching assembly including:
a gallium nitride switch having a gate terminal, drain terminal and source terminal;
a gate driver generating a drive signal in response to the control signal;
a gate drive circuit including a turn on resistor in series with the gate driver and the gate terminal and a clamping circuit connected across the gate terminal and the source terminal, a turn on drive signal from the gate driver being applied to the gate terminal through the turn on resistor; and
a snubber circuit connected across the drain terminal and source terminal.

14. The elevator drive unit of claim 13, the switching assembly further comprising:
a turn off resistor in series with the gate driver and the gate terminal, a turn off drive signal from the gate driver being applied to the gate terminal through the turn off resistor.

15. The elevator drive unit of claim 13 wherein:
the clamping circuit includes a capacitor connected across the gate terminal and the source terminal.

16. The elevator drive unit of claim 13 wherein:
the clamping circuit includes a resistor and capacitor in parallel, the resistor and capacitor connected across the gate terminal and the source terminal.

17. The elevator drive unit of claim 13, the switching assembly further comprising:
a second gallium nitride switch having a gate terminal, drain terminal and source terminal, the second gallium nitride switch in parallel with the gallium nitride switch;
a second gate drive circuit including a second turn on resistor in series with the gate driver and the gate terminal of the second gallium nitride switch and a second clamping circuit connected across the gate terminal and the source terminal of the second gallium nitride switch, the turn on drive signal from the gate driver being applied to the gate terminal of the second gallium nitride switch through the second turn on resistor.

18. The elevator drive unit of claim 13 wherein:
wherein the elevator drive unit is configured to operate without a dedicated heat sink.
